(19) United States
(12) Patent Application Publication
(10) Pub. No.: US 2002/0156550 A1
(43) Pub. Date: Oct. 24, 2002

(54) Robust windowing method using the poisson yield model for determining the systematic and random yield of failing circuits on semiconductor wafers

(76) Inventor: Rick Edward Langford, Singapore (SG)

Correspondence Address: David M. Carter, Esq., Dilworth & Barrese, LLP, 333 Earle Ovington Blvd., Uniondale, NY, 11553, US

(21) Appl. No.: 09/795,415

(22) Filed: Feb. 28, 2001

(51) Int. Cl. G06F 19/00; H01L 21/66; G01R 31/26

(52) U.S. Cl. 700/110; 700/109; 438/14

(57) ABSTRACT

A robust windowing method of extracting Y₀ and D₀ values from wafer maps for utilizing the Poisson yield model is provided, in order to determine defects (i.e., failed circuits) associated with a batch of semiconductor wafers. Application of the method of the present invention provides an effective, parameter independent method of detecting reticle and repeating defects.

### BACKGROUND OF THE INVENTION

1. Field of the Invention

The present invention relates generally to the area of manufacturing yield models. Specifically, the present invention relates to a robust windowing method applied to the Poisson yield model for determining the systematic and random yield components of failing circuits on semiconductor wafers and to detect reticle and repeating defects causing the failed circuits.

2. Description of the Related Art

The most common technique for manufacturing integrated circuits is the planer technology method, whereby individual circuits are formed below the surface of a semiconductor substrate (i.e., a wafer). The planer technology method is conventionally practiced by first fabricating an ingot of substantially pure semiconductor material which is then sliced to yield individual wafers. Next, at least one layer of semiconductor material of a different type is formed (i.e., epitaxially grown) on the upper surface of each wafer. Thereafter, the surface of the upper epitaxial layer on each wafer is passivated, and then is selectively etched by photolithographic techniques to create openings in which semiconductor junctions are formed. After formation of the semiconductor junctions, interconnections between the junctions in each wafer are formed by depositing a metal such as aluminum.

Once the individual circuits are formed on each wafer, the circuits are tested by probing using a conventional probe designed for that purpose. Those circuits which are found to be defective during probing are recorded as to their location on the semiconductor wafer. Following probing, each wafer is then diced into circuit-containing chips, the defect-free ones of which are thereafter each separately packaged to yield individual integrated circuits.

As may be appreciated, the manufacture of integrated circuits by the above-described method is complex and involves many different process steps. Failure to execute one or more process steps correctly on one or more wafers in a batch will likely cause one or more circuits on each wafer to fail. Further, random defects that may or may not cause a circuit failure can and do occur. Usually, there is little that can be done to avoid random defects. Often, however, failing circuits and/or defects are spatially clustered as a result of one or more process steps being improperly executed or the occurrence of defect generating events. A knowledge of which of the process steps was not properly executed can lead to improved performance through process modification.

Accordingly, it is generally desired to predict yield before committing to a series of process steps to manufacture a product, such as semiconductor circuits. Manufacturing yield models are used to bridge from monitor to product, to bridge from product to product, or to predict yield before committing to a product. That is, manufacturing yield models are used to estimate the future yield of a current or new product and yield loss from each of the process steps. The Wallmark's model is known as one of the earliest yield models. Among the models developed after this, the Poisson yield model and negative binomial yield model are most frequently used. The Poisson yield model assumes that the distribution of defects or faults is random and the occurrence of a defect at any location is independent of the occurrence of any other defect.

The Poisson yield model is generally used in circuit chip fabrication to determine for a given number of failed circuits on a semiconductor wafer caused by defects, μ, the probability, Yₖ, that a semiconductor wafer contains k failed circuits. The Poisson yield model equation used to determine the probability, Yₖ, that the semiconductor wafer contains k failed circuits is:

$${Y}_{k} = \frac{{ⅇ}^{- μ} {μ}^{k}}{k !}$$

where k=0, 1, 2, . . .

Since the yield is equivalent to the probability that the semiconductor wafer contains no failed circuit, the Poisson yield model is typically represented as:

Y=Y₀e^{31 A}^{_{C}}^{D}^{₀} Equation 1

where A_{c} represents a critical area; that is, the area where the center of a failed circuit must fall to create a fault. D₀ represents the average defect density of all failed circuit sizes. Therefore, the average number fault-causing defects per die, μ, is obtained by μ=A_{C}D₀.

The expression for the Poisson yield model in Equation 1 shows yield as the product of two components of yield loss. The first, Y₀, represents non-random yield loss. This yield loss is independent of area, and is often interpreted as limited yield, meaning that no matter how clean the process is, yield is still limited by Y₀. The remaining expression of the yield model represents random defect induced yield loss. The yield term, Y, can be interpreted as a measure of functional die or good die yield.

In order to utilize the Poisson yield model the values of Y₀ and D₀A_{C} must be determined for a particular semiconductor wafer. These values can be extracted from wafer probe bin map data by utilizing the Poisson yield model and the spatial characteristics of failing circuits on the wafer. Advanced methods for extracting the Y₀ and D₀ values employ a multi-die windowing method. The multi-die windowing method entails using a windowing technique that combines multiple die into super chips with total area being a multiple of the area of an individual die and then fitting the yield model to these results.

A related method of combining each die on a semiconductor wafer with a neighbor until all die are included in a window for several size windows is described in Stapper, C. H., “Large-area Fault Clusters and Fault Tolerance in VLSI Circuits: A Review,” IBM Journal of Research and Development, vol. 33, pp. 162-173, March 1989. The method described in Stapper entails every die being included in only one super chip and repeating for several super chip sizes. The method does not fully utilize the spatial distribution of defects in determining the yield impact on theoretically larger area devices, i.e., super chips, by ignoring most combinations of die that can form super chips. The method is also difficult to automate as it is layout dependent.

Hansen, M. H., et al., “Circuit Fabrication Processes for Spatially Clustered Defects,” Technometrics, vol. 39, pp. 241-253, August 1997, describes a method of combining die with all neighbors, and subsequently separating random from non-random defects using a statistically-based method. The method includes difficulties in determining a threshold for separating random from non-random defects and automation of the technique to a yield model has not been demonstrated.

### SUMMARY OF THE INVENTION

In accordance with the present invention, a robust windowing method of extracting Y₀ and D₀ values from wafer maps utilizing a robust windowing method applied to the Poisson yield model is disclosed, in order to determine yield components (i.e., systematic and random) associated with a batch of semiconductor wafers.

One method of the present invention determines defects (systematic or random) associated with a semiconductor wafer having a plurality of die each having a circuit fabricated therein by subjecting the semiconductor wafer to a plurality of separate process operations. The method includes the steps of: a) combining a pivot die of an mxm die matrix, where m is an integer, with (n−1) neighbor die to create a multi-die chip having an n-die window, where n is an integer; b) determining a yield, Yₙ, for the n-die window multi-die chip by dividing the number of yielding n-die super chips by the total number of n-die super chips, c) repeating steps (a) and (b) to create additional multi-die chips having different window sizes and to determine a yield for the additional multi-die chips; and d) using a weighted regression technique to obtain an optimal solution for Y₀ and D₀ using the values of Yₙ for the multi-die chip and the additional multi-die chips using the following equation (a variation of the Poisson yield model equation):

Yₙ=Y₀e^{-μn.},

where Y₀ represents non-random yield loss and μrepresents an average number of non-functional circuits caused by defects.

### BRIEF DESCRIPTION OF THE DRAWINGS

The invention is further explained by way of example and with reference to the accompanying drawings, wherein:

FIG. 1 illustrates a pivot die combined with neighbor die to create two-, three-, four-, six- and nine-die super chips according to the present invention;

FIG. 2 illustrate wafer maps plotted on a scatter plot of systematic versus functional yield;

FIG. 3 illustrates a wafer map as an example of a low yielding large die size wafer, where the functional die are shown in black, having a Y₀, value of 1.106 using the method according to the present invention;

FIGS. 4 and 5 are graphs illustrating a situation in which a reticle defect affected 10 lots of a particular code; and

FIG. 6 illustrates a wafer map as an example of a high yielding large die size wafer, where the functional die are shown in black, having a reticle defect.

### DETAILED DESCRIPTION OF THE PREFERRED EMBODIMENTS

The robust windowing method of extracting Y₀ and D₀ values from wafer maps for utilizing the Poisson yield model, in order to determine defects (i.e., failed circuits) associated with a batch of semiconductor wafers, in accordance with the present invention, will now be described. Application of the method of the present invention provides an effective, parameter independent method of detecting reticle and/or repeating defects. Once a reticle and/or repeating defect is detected using the method of the present invention, a technician may then perform corrective action to eliminate such a defect.

The method of the present invention will now be described and then followed by a discussion of a case study where the method of the present invention was applied to determine functional yield die for codes of a given semiconductor manufacturing technology.

I. Methodology

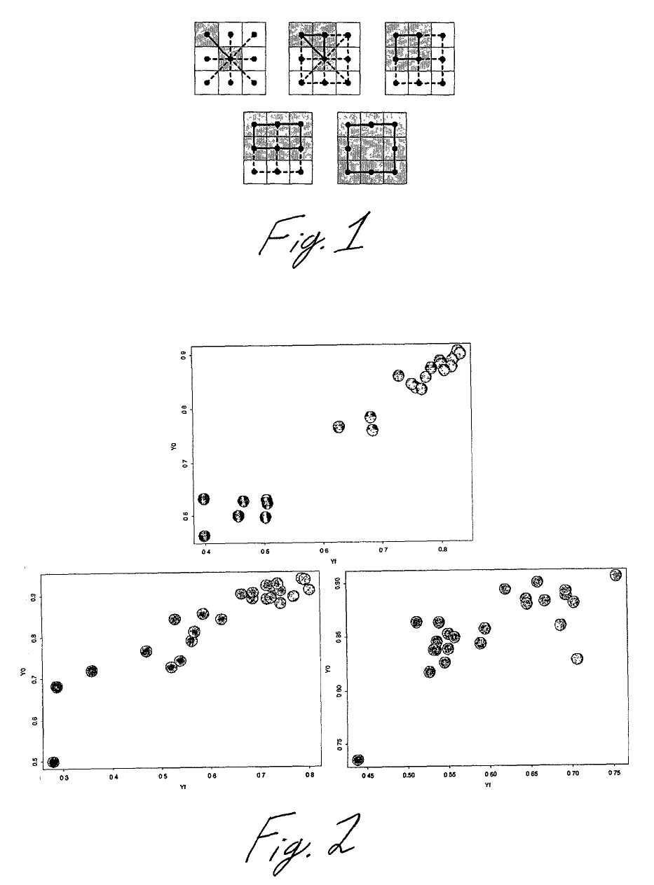

With reference to FIG. 1, in one embodiment of the present invention, a 3×3 die matrix with a central pivot die is considered. The pivot die is combined with (n−1) neighbor die to create multi-die super chips (i.e., two-, three- four-, six- and nine-die super chips) having an n-die window, as illustrated in FIG. 1, where the shaded die and solid connecting lines indicate one super chip combination and dashed lines indicate all other combinations. For a 3×3 matrix with a single pivot die, as shown by FIG. 1, up to eight two- and three-die super chips, up to four four- and six-die super chips, and one nine-die super chip are possible.

For each die on a semiconductor wafer as the pivot die, all super chip combinations as shown in FIG. 1 are considered. In the case of edge die, only complete super chips are considered. A multi-die super chip is considered yielding only if all die of that super chip are determined to be functional die. That is, if the circuit of each die of the multi-die super chip is functional. The yield for an n-die window super chip, Yₙ, is equal to the total number of yielding super chips divided by the total number of complete super chips (i.e., the total number of super chips which are possible by the matrix).

The values of Yₙ, for several window sizes can then be used in the solution of Equation 1. However, since each window of the n-die window super chip is a multiple of the same area, the expression for Y is restated using n as an area multiplier. The yield for the n-die window super chip, Yₙ, is then described by:

Yₙ=Y₀e^{-D}^{₀}^{nA}^{_{C}} Equation 2

which can also be represented as:

Yₙ=Y₀e^{-μn}.

An optimal solution for Equation 2 is then obtained with the weighted regression technique. Only non-zero Yₙ's are considered, and solutions are only attempted for semiconductor wafers with three or more non-zero Yₙ's. The solution of Equation 2 is found to be sensitive to the value of the weighting factors, Wₙ. As the multi-die super chip area increases, the confidence in the value of Yₙ decreases. As a result, Wₙ was made to be a function that decreases rapidly with increasing window size:

Wₙ=W₁C⁻ⁿ, for n>1 Equation 3

Optimum weighting factor values were determined by finding the lowest value of the weighting coefficient, C, that results in Y₀ and D₀, which when used in Equation 1 to calculate Y, gave the actual value of Y for the semiconductor wafer. Table 1 summarizes exemplary results for various values of C for a particular semiconductor wafer. Based on these results, C=5 with W₁=1 was used in the case study.

TABLE 1
Effects of weighting coefficients.

| C | Y₀ | D₀ | ΔY |
|---|---|---|---|
| 1 | 1.010228 | 1.204922 | −4.267E-02 |
| 2 | 0.79159 | 1.100373 | −7.510E-03 |
| 3 | 0.739261 | 1.055619 | −2.382E-03 |
| 4 | 0.714608 | 1.028957 | −1.0113E-03 |
| 5 | 0.69979 | 1.011139 | −5.126E-04 |
| 6 | 0.689826 | 0.99847 | −2.912E-04 |
| 7 | 0.682671 | 0.989076 | −1.768E-04 |
| 8 | 0.677301 | 0.981852 | −1.177E-04 |
| 9 | 0.673134 | 0.97617 | −8.088E-05 |
| 10 | 0.669817 | 0.971595 | −5.822E-05 |

II. Results

The calculation of Yₙ using one, two, three, four, six and nine die windowing schemes and weighted regression solution is preferably implemented by converting the steps of the method of the present invention into a set of programmable instructions which are executed by a processor. For example, a processor of a wafer map analysis system.

III. Predictive Ability

In order to measure the accuracy of the resultatnt D₀ and Y₀ values of the inventive method for predicting yield of the semiconductor wafer, the median values of Y₀ and D₀, for all semiconductor wafers of a given technology were determined. These median values were then used to calculate the yield for a variety of device types of various areas of that technology, using only each code's total area, A. The resulting yields, i.e., Y_{f} Mean, were then compared to the actual yields, i.e., Y_{f} Model, and an error was determined by using the difference between these values.

The results have shown that the extracted Y₀ and D₀ terms are indicative of the systematic and random yield loss characteristic of the technology under study. Once these characteristics (Y₀ and D₀) of a technology are known, the values can the be applied to a circuit of the same technology before fabrication to predict its yield.

IV. Indicative of Spatial Non-randomness

An important capability gained when extracting Y₀ for every wafer produced is the use of the extracted Y₀ as an indicator of spatial non-randomness. This relationship is demonstrated in FIG. 2 where wafer maps are plotted on a scatter plot of systematic versus functional yield.

The wafer maps for the three lots shown by FIG. 2 vary from a strong spatial signature for one lot (top graph in FIG. 2), to a depressed center of some wafers for another lot (bottom left graph in FIG. 2), and to a lot dominated by random failures. In each case, Y₀ is found to be an indicator of the degree of spatial non-randomness which can be used to identify abnormal wafers, i.e., wafers that include an abnormal formation (see FIG. 6), by automatically flagging wafers that may require further investigation. Qualitative analysis of the types of plots shown by FIG. 2 and the extraction of rogue wafers based on systematic yield loss for a large data set has confirmed the inventive method's ability to separate systematic and random yield components.

As D₀ has been conventionally used to monitor a cleanroom's performance, Y₀, using the present invention, could be used to monitor process improvements. As a tool to aid yield improvement, in accordance with the present invention, Y₀ can be used in equipment commonality studies, wafer position analysis and other correlations to identify the causes of yield problems, and make adjustments/improvements to the equipment or process.

V. Exceptions to the Model

In the data set analyzed, there were several case where Y₀ was found to be greater than 1.0 for large area devices. This is clearly a case where the model does not fit. FIG. 4 shows several such cases. Typically, two major causes of wafers not fitting the model are sparse functional die for large area devices and reticle defects. In both cases, the yield rapidly drops to zero as the super chip size increases.

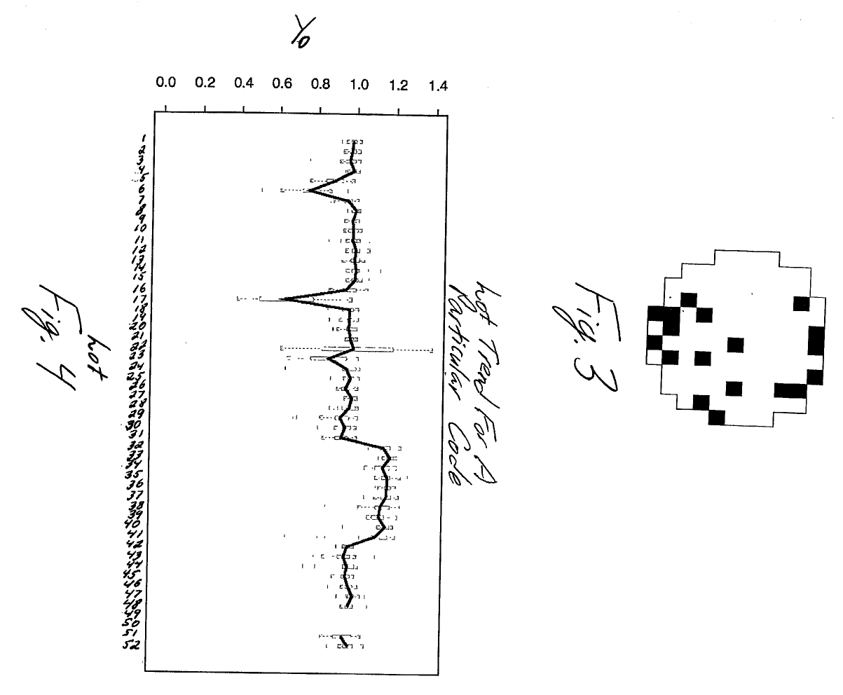

In the first case, large die size products, with few functional die, result in rapidly decreasing yield as the window size increases. The method is limited by the consideration of discrete increments in area. For large die sizes, the resolution of area increments is very low, and the yield drops to zero before all window sizes are considered. This is due in part to the initial low yield and also due to the large incremental increases in area of the multiple die windows, since the initial area is large. The wafer map shown in FIG. 3 is an example of a low yielding large die size wafer and has a Y₀ value of 1.106 using the method of the present invention.

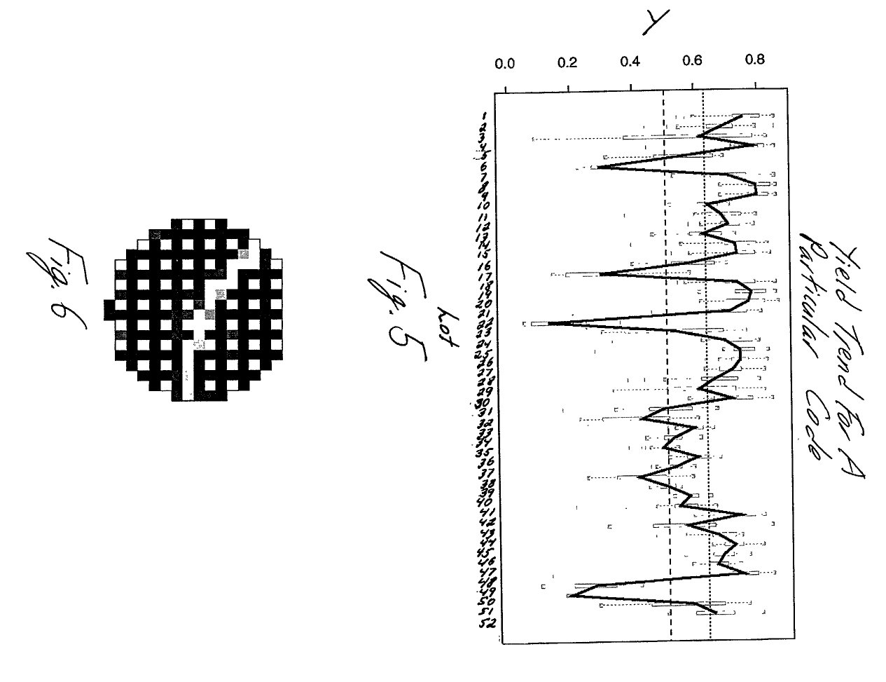

Wafers that give Y₀ greater than one are in such small numbers that the median Y₀ for a lot is rarely above 1.0. One exception to this is the case of a reticle and/or repeating defect. FIGS. 4 and 5 show the situation in which a reticle defect affected 10 lots, i.e., lots 32-41, of a particular code having at least lots numbered 1-52. The lot trend of Y₀ (FIG. 4) shows a very clear signal of the problem, while the dip in the yield trend (FIG. 5) is much less evident in the normal variation in yield. Only three lots yielded below the hold limit during this excursion, i.e., lots 32, 35, and 38.

The seriousness of the defect affecting these lots is clear in the composite map for a particular lot in FIG. 6, where white indicates a zero yield location.

A significant finding in implementing the method of the present invention is that even results for wafers not fitting the model are of value; providing a totally parameter independent method of detecting repeating defects, where traditional methods require knowledge of the number and layout of die in the reticle field and the application of a statistical test of yield difference by reticle site.

In summary, the windowing method of the present invention is used to calculate the yield of dies with 2, 3, 4, 6, 9, . . . times the original die area. The calculated yields along with the actual yield (n=1) are then used in Equation 2 with a weighted regression fit to determine D₀ and Y₀, for each semiconductor wafer. Overall values are then obtained for a code and technology by taking the median of code level medians. The overall technology values are then used to predict the yield of a new code of the same technology.

In conclusion, the windowing method of extracting Poisson yield model Y₀, and D₀ values from wafer probe bin map data, according to the present invention, is robust and easily implemented in a system for large scale wafer map analysis. The resulting parameters give reasonable predictive results when applied to products of similar type and technology. It has also been shown that the calculation of per wafer Y₀ values give a useful metric for yield improvement and monitoring process performance. This measure has also been shown to be a powerful, parameter independent means of identifying wafers affected by reticle and/or repeating defects.

Although the illustrative embodiment of the present disclosure has been described herein with reference to the accompanying tables and drawings, it is to be understood that the disclosure is not limited to that precise embodiment, and that various other changes and modifications may be affected therein by one skilled in the art. For example, the method of the present invention may be implemented using 4×4, 5×5, . . . , mxm die matrices, where n is an integer. That is, those skilled in the art will envision other modifications within the scope and spirit of the claims appended hereto.

What is claimed is:

1. A method for determining defects associated with a semiconductor wafer having a plurality of die each having a circuit fabricated therein by subjecting the semiconductor wafer to a plurality of separate process operations, the method comprising the steps of:
a) combining a pivot die of an mxm die matrix, where m is an integer, with (n−1) neighbor die to create a multi-die chip having an n-die window, where n is an integer;
b) determining a yield, Yₙ, for the n-die window multi-die chip by dividing the number of yielding n-die chips by the total number of n-die chips;
c) repeating steps (a) and (b) to create additional multi-die chips having different window sizes and to determine a yield for the additional multi-die chips; and
d) using a weighted regression technique to obtain an optimal solution for Y₀ and D₀ using the values of Yₙ for the multi-die chip and the additional multi-die chips, using the following equation:
Yₙ=Y₀e^{-μn.},
where Y₀ represents non-random yield loss and μ represents an average number of non-functional circuits caused by defects.

2. The method according to claim 1, wherein step (d) utilizes the following equation:
Wₙ=W₁C⁻ⁿ, for n>1
where Wₙ represents weighting factor values, and C represents a weighting coefficient.

3. The method according to claim 2, further comprising the step of determining weighting factor values, Wₙ, by determining the lowest value of the weighting coefficient, C, that results in Y₀ and D₀ when used in the Poisson yield model equation to provide the actual yield, Y, for the semiconductor wafer.

4. The method according to claim 3, further comprising the step of using Y₀ as an indicator of spatial non-randomness for identifying whether the semiconductor wafer includes an abnormal formation.

5. The method according to claim 3, further comprising the step of using Y₀ to identify causes affecting the actual yield, Y, of the semiconductor wafer.

6. The method according to claim 1, further comprising the step of converting steps (a) to (d) into a set of programmable instructions for being executed by a processor.

7. The method according to claim 1, further comprising the step of measuring the predictive ability of the method steps to predict the yield of the semiconductor wafer.

8. The method according to claim 1, further comprising the step of detecting reticle and/or repeating defects.

9. The method according to claim 8, further comprising the step of performing a correction action to eliminate a reticle and/or repeating defect.
